(19) United States
(12) Patent Application Publication
(10) Pub. No.: US 2024/0298452 A1
(43) Pub. Date: Sep. 5, 2024

(54) FERROELECTRIC MEMORY DEVICE WITH STACKED CAPACITORS AND MANUFACTURING METHOD THEREOF

(71) Applicant: Wuxi Smart Memories Technologies Co., Ltd., Wuxi (CN)

(72) Inventor: Yushi HU, Wuxi (CN)

(73) Assignee: Wuxi Smart Memories Technologies Co., Ltd., Wuxi (CN)

(21) Appl. No.: 18/660,327

(22) Filed: May 10, 2024

Related U.S. Application Data
(63) Continuation of application No. PCT/CN2021/130508, filed on Nov. 15, 2021.

(51) Int. Cl. H10B 53/30

(52) U.S. Cl. CPC H10B 53/30

(57) ABSTRACT

A ferroelectric memory cell includes a transistor pair having a first source region, a second source region, a first gate structure, a second gate structure, a first drain region, and a second drain region, a first ferroelectric capacitor formed on and electrically connected to the first drain region, a first plateline formed on and electrically connected to the first ferroelectric capacitor, and a second ferroelectric capacitor formed on and electrically connected to the first plateline. The second ferroelectric capacitor is electrically connected to the second drain region.

### CROSS-REFERENCE TO RELATED APPLICATIONS

This application is a continuation of International Application No. PCT/CN2021/130508, filed on Nov. 15, 2021, which is incorporated herein by reference in its entirety.

### BACKGROUND

The present disclosure relates to ferroelectric memory devices and manufacturing methods thereof.

The nonvolatile Ferroelectric Random Access Memory (FeRAM or FRAM) are promising candidates for future nonvolatile memory devices because of their low voltage, low power consumption, great endurances, and fast read and write speed. The mechanism of FeRAM is based upon the properties of a ferroelectric dielectric of ferroelectric capacitors of ferroelectric memory cells that have a reversible electric polarization. By applying an electric field across the ferroelectric dielectric, the polarization of the ferroelectric dielectric may be reversed or reoriented and therefore the state of the ferroelectric memory cells may be switched from “0” to “1” or vice versa.

### SUMMARY

According to one aspect of the present disclosure, a ferroelectric memory cell includes a transistor pair having a first source region, a second source region, a first gate structure, a second gate structure, a first drain region, and a second drain region, a first ferroelectric capacitor formed on and electrically connected to the first drain region, a first plateline formed on and electrically connected to the first ferroelectric capacitor, and a second ferroelectric capacitor formed on and electrically connected to the first plateline. The second ferroelectric capacitor is electrically connected to the second drain region.

In some embodiments, the ferroelectric memory cell further includes a first interconnect layer formed on the second ferroelectric capacitor and electrically connected between the second ferroelectric capacitor and the second drain region.

In some embodiments, the first plateline includes an extended portion configured to be a routing structure.

In some embodiments, the first plateline includes an extended portion connected to a routing structure.

In some embodiments, the first plateline includes a mesh pattern.

In some embodiments, the ferroelectric memory cell further includes a first contact electrically connected between the first ferroelectric capacitor and the first drain region, and a second contact electrically connected between the second ferroelectric capacitor and the second drain region.

In some embodiments, the first ferroelectric capacitor includes a first bottom electrode, a first ferroelectric dielectric on the first bottom electrode, and a first top electrode on the first ferroelectric dielectric. The second ferroelectric capacitor includes a second bottom electrode, a second ferroelectric dielectric on the second bottom electrode, and a second top electrode on the second ferroelectric dielectric.

In some embodiments, the second top electrode is in contact with the second contact and electrically connected between the second ferroelectric capacitor and the second drain region.

In some embodiments, the first ferroelectric dielectric and the second ferroelectric dielectric include hafnium oxide (HfOₓ), zirconium oxide (ZrOₓ), titanium oxide (TiOₓ), aluminum oxide (AlOₓ), nickel oxide (NiOₓ), iron oxide (FeOₓ).

In some embodiments, the ferroelectric memory cell further includes a first blocking layer formed on sidewalls of the first bottom electrode, the first ferroelectric dielectric, and the first top electrode, and a second blocking layer formed on sidewalls of the second bottom electrode, the second ferroelectric dielectric, and the second top electrode.

In some embodiments, the first ferroelectric capacitor and the second ferroelectric capacitor are in align with each other in a first direction.

In some embodiments, the ferroelectric memory cell further includes a third ferroelectric capacitor formed on and electrically connected to the first interconnect layer, and a second plateline formed on and electrically connected to the third ferroelectric capacitor.

In some embodiments, the ferroelectric memory cell further includes a fourth ferroelectric capacitor formed on and electrically connected to the second plateline. The fourth ferroelectric capacitor is electrically connected to the first ferroelectric capacitor.

According to another aspect of the present disclosure, a ferroelectric memory device includes a plurality of ferroelectric memory cells, each ferroelectric memory cell includes a transistor pair having a first source region, a second source region, a first gate structure, a second gate structure, a first drain region, and a second drain region, a first ferroelectric capacitor formed on and electrically connected to the first drain region, a first plateline formed on and electrically connected to the first ferroelectric capacitor, and a second ferroelectric capacitor formed on and electrically connected to the first plateline. The second ferroelectric capacitor is electrically connected to the second drain region.

In some embodiments, each ferroelectric memory cell stores two bits.

In some embodiments, the first plateline is configured to be shared among ferroelectric capacitors of the plurality of ferroelectric memory cells laterally.

In some embodiments, the first plateline is electrically connected to a plateline driver such that a write voltage can be introduced into the plurality of ferroelectric memory cells by the plateline driver.

According to yet another aspect of the present disclosure, a method for manufacturing a ferroelectric memory cell includes forming a transistor pair including a first source region, a second source region, a first gate structure, a second gate structure, a first drain region, and a second drain region on a substrate, forming a first bit line on the first source region, a second bit line on the second source region, a first word line on the first gate structure, and a second word line on the second gate structure, forming a first contact on the first drain region, forming a first ferroelectric capacitor on the first contact, forming a first plateline on the first ferroelectric capacitor, forming a second ferroelectric capacitor on the first plateline, and forming an interconnect layer on the second ferroelectric capacitor. The interconnect layer is connected between the second drain region and the second ferroelectric capacitor.

In some embodiments, forming a first ferroelectric capacitor on the first contact includes sequentially forming a first bottom electrode layer, a first ferroelectric dielectric layer, and a first top electrode layer, and etching the first bottom electrode layer, the first ferroelectric dielectric layer, and the first top electrode layer to form a first bottom electrode, a first ferroelectric dielectric, and a first top electrode.

In some embodiments, the method further includes forming a first sacrificial blocking layer on sidewalls of the first bottom electrode, the first ferroelectric dielectric, and the first top electrode, and a top surface of the first top electrode, etching to expose the top surface of the first top electrode to form a first blocking layer, and forming the first plateline on the top surface of the first top electrode.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of an exemplary ferroelectric memory device, according to some aspects of the present disclosure.

FIG. 2A illustrates a plan view of an exemplary ferroelectric memory cell, according to some aspects of the present disclosure.

FIG. 2B illustrates a side view of a cross-section of the exemplary ferroelectric memory cell in FIG. 2A, according to some aspects of the present disclosure.

FIG. 3A illustrates a plan view of an exemplary ferroelectric memory cell, according to some aspects of the present disclosure.

FIG. 3B illustrates a side view of a cross-section of the exemplary ferroelectric memory cell in FIG. 3A, according to some aspects of the present disclosure.

FIG. 3C illustrates a side view of a cross-section of an exemplary ferroelectric memory cell, according to some aspects of the present disclosure.

FIG. 3D illustrates a side view of a cross-section of an exemplary ferroelectric memory cell, according to some aspects of the present disclosure.

FIG. 4 illustrates a plan view of an exemplary ferroelectric memory device, according to some aspects of the present disclosure.

FIG. 5A illustrates a side view of a cross-section of an exemplary ferroelectric memory device, according to some aspects of the present disclosure.

FIG. 5B illustrates another side view of a cross-section of an exemplary ferroelectric memory device, according to some aspects of the present disclosure.

FIG. 6 illustrates a side view of a cross-section of an exemplary ferroelectric memory device, according to some aspects of the present disclosure.

FIG. 7 illustrates a side view of a cross-section of an exemplary ferroelectric memory device, according to some aspects of the present disclosure.

FIGS. 8A-8H illustrate a fabrication process for forming an exemplary ferroelectric memory device, according to some aspects of the present disclosure.

FIG. 9 illustrates a flowchart of a method for forming an exemplary ferroelectric memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some implementations,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, the term “vertical/vertically” means nominally perpendicular to the lateral surface of a substrate. And the term “lateral/laterally” means nominally parallel to the lateral surface of a substrate.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

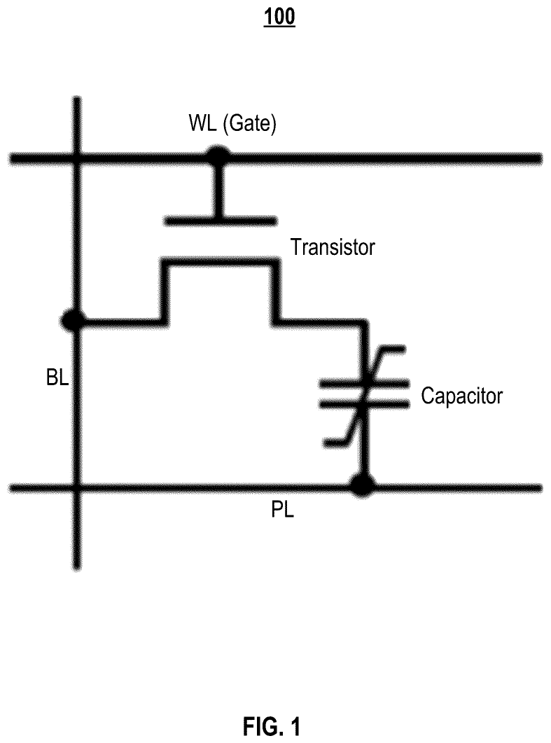

Ferroelectric Random Access Memory (FeRAM) or ferroelectric memory cells are non-volatile memory devices that store data using a ferroelectric dielectric material in a ferroelectric capacitor. Generally, there are two types of FeRAM configuration. One is a one-transistor-one-capacitor (1T1C) type, which is composed of one transistor and one ferroelectric capacitor, as shown in FIG. 1, and the other is one-transistor (1T) type or also called field-effect transistor (FET) type, which is composed of a single ferroelectric-gate FET. The 1T1C ferroelectric memory cell is similar to a 1T1C Dynamic Random Access Memory (DRAM) memory cell. Both cells use the word line and the bit line with the same topology. The general difference between the two memory cells at the circuit level is that ferroelectric memory cells use the plateline instead of the ground line as in the DRAM memory cell. Since the characteristic of the ferroelectric dielectric in the capacitor of ferroelectric memory cell is different from the dielectric in the capacitor of the DRAM memory cell, the state of the ferroelectric dielectric needs to be switched by a voltage from a plateline as well as a voltage from the bit line. It is noted that the present disclosure does not limit to the 1T1C type of FeRAM configuration, but also includes 2T2C, 3T3C, . . . , nTnC, or nTmC (where n and m are integers).

In particular, to write “0” (positive polarization state) to a ferroelectric memory cell, a positive write voltage is applied to a bit line while a plateline is grounded and a word line is asserted. On the contrary, to write “1” (negative polarization state) to the ferroelectric memory cell, a positive write voltage is applied to the plateline while the bit line is grounded, and the word line is asserted.

Although the 1T1C ferroelectric memory cell is similar to a 1T1C Dynamic Random Access Memory (DRAM) memory cell and thus can be an excellent candidate or a replacement of DRAM memory cell in various kinds of applications, the conventional two-dimensional (2D), or planer cell structure of ferroelectric memory cell is not effective due to the large area size of the ferroelectric capacitor. Specifically, the area size of the ferroelectric capacitor may not be reduced to below a certain range, e.g., less than 0.25 μm². Therefore, the density of ferroelectric memory cells becomes a huge challenge that limits the application of ferroelectric memory devices.

To address one or more of the aforementioned issues, the present disclosure introduces a solution in which a stacked ferroelectric capacitor structure is introduced and a plateline is placed between the two ferroelectric capacitors of the stacked ferroelectric capacitor structure such that two ferroelectric capacitors can be stacked and thus the area size is reduced. Furthermore, in certain situations of the conventional 2D cell structure of 1T1C FeRAM configuration, the unit area per bit is limited by the ferroelectric capacitor area rather than the transistor area. Therefore, by stacking the ferroelectric capacitors, e.g., 2 stacks, 4 stacks, 8 stacks, or more, the chip density can be increased significantly.

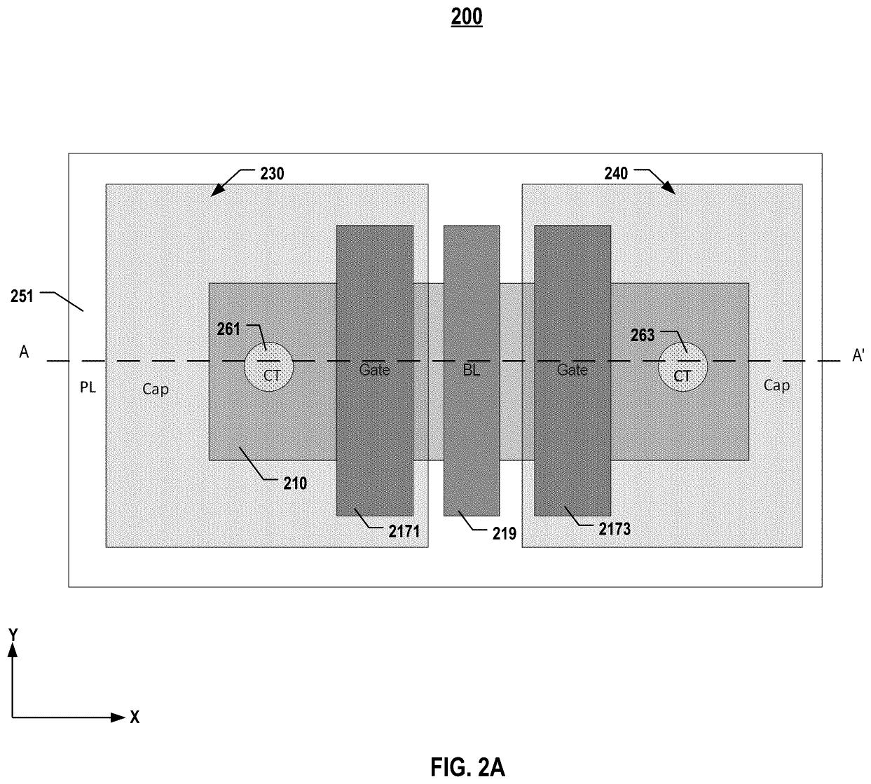

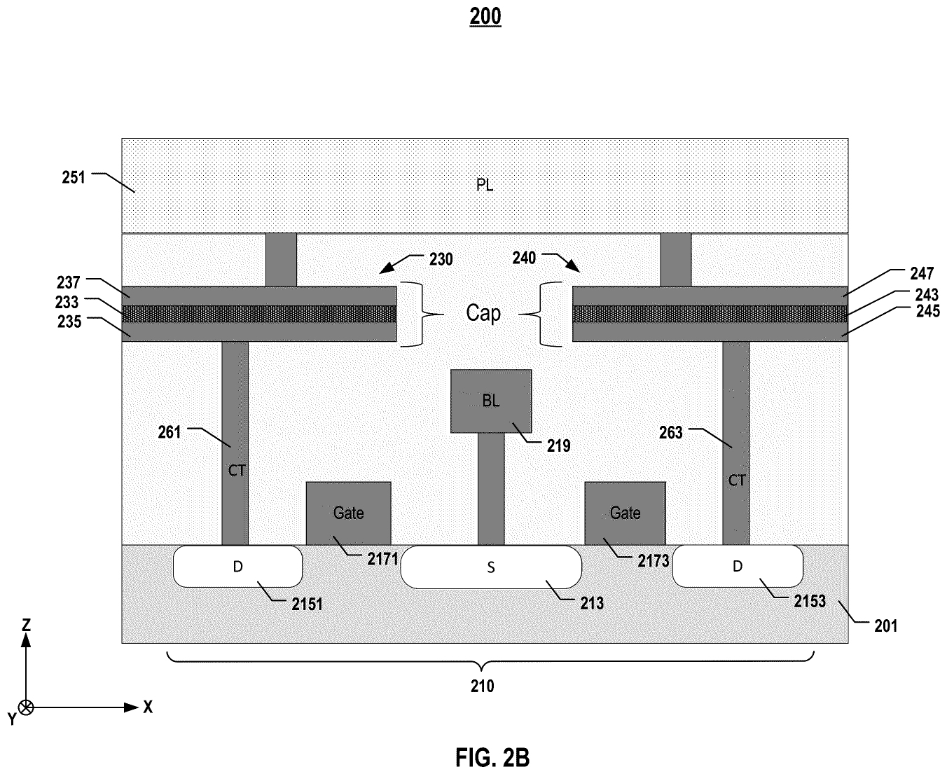

FIG. 2A illustrates a plan view of a ferroelectric memory cell 200, according to some aspects of the present disclosure, and FIG. 2B illustrates a side view of a cross-section ferroelectric memory cell 200 along the AA′ direction in FIG. 2A. As shown in FIGS. 2A and 2B, ferroelectric memory cell 200 includes a transistor pair 210 having a common source region 213 in a substrate 201, a first gate structure 2171 and a second gate structure 2173 on substrate 201, and a first drain region 2151 and a second drain region 2153 in substrate 201. Ferroelectric memory cell 200 may further include a common bit line 219 formed on and electrically connected to common source region 213, a first word line included in first gate structure 2171 or electrically connected to first gate structure 2171, a second word line included in second gate structure 2173 or electrically connected to second gate structure 2173, a first ferroelectric capacitor 230 formed on and electrically connected to first drain region 2151 via a first contact 261, a second ferroelectric capacitor 240 formed on and electrically connected to second drain region 2153 via a second contact 263, and a plateline 251 formed on and electrically connected to first ferroelectric capacitor 230 and second ferroelectric capacitor 240, respectively. In some embodiments, common source region 213 and other common source region disclosed herein may be two separated source regions, e.g., a first source region and a second source region. In some embodiments, common bit line 219 and other common bit lines disclosed herein may be two separated bit lines, e.g., a first bit line and a second bit line. First ferroelectric capacitor 230 includes a first top electrode 237, a first bottom electrode 235, and a first ferroelectric dielectric 233 between first top electrode 237 and first bottom electrode 235. Second ferroelectric capacitor 240 includes a second top electrode 247, a second bottom electrode 245, and a second ferroelectric dielectric 243 between second top electrode 247 and second bottom electrode 245. In some embodiments, first ferroelectric capacitor 230 and second ferroelectric capacitor 240 may have the same area size. As shown in the plan view of ferroelectric memory cell 200 in FIG. 2A, the two ferroelectric capacitors dominate the entire chip size and therefore limit the density of the ferroelectric memory device. It is noted that each transistor pair (e.g., transistor pair 210) may include two transistors, which means each ferroelectric memory cell 200 has a transistor pair and two ferroelectric capacitors may be able to store two bits.

Substrate 201 may include silicon (e.g., single crystalline silicon), silicon germanium (SiGe), gallium arsenide (GaAs), germanium (Ge), silicon on insulator (SOI), or any other suitable materials. In some embodiments, substrate 201 is p-doped or includes a p-doped region surrounding common source region 213, first drain region 2151, and second drain region 2153. In some embodiments, common source region 213, first drain region 2151, and second drain region 2153 are n-doped regions. Each of first gate structure 2171 and second gate structure 2173 may include a respective gate dielectric and a respective gate electrode on the gate dielectric.

Common bit line 219 (or, in some embodiments, a first bit line and a second bit line), first and second word lines 2171 and 2173, first contact 261, second contact 263, and plateline 251 can include conductive materials including, but not limited to, tungsten (W), cobalt (Co), copper (Cu), aluminum (Al), polysilicon, doped silicon, silicide, or any combination thereof. In some embodiments, each of common bit line 219, first and second word lines 2171 and 2173, and plateline 251 includes a metal, such as tungsten. In some embodiments, plateline 251 may include carbon.

First top electrode 237, first bottom electrode 235, second top electrode 247, and second bottom electrode 245 can include conductive materials including, but not limited to, titanium nitride (TiN), titanium silicon nitride (TiSiNₓ), titanium aluminum nitride (TiAlNₓ), titanium carbon nitride (TiCNₓ), tantalum nitride (TaNₓ), tantalum silicon nitride (TaSiNₓ), tantalum aluminum nitride (TaAlNₓ), tungsten nitride (WNₓ), tungsten silicide (WSiₓ), tungsten carbon nitride (WCNₓ), ruthenium (Ru), ruthenium oxide (RuOₓ), iridium (Jr), doped polysilicon, transparent conductive oxides (TCO), or iridium oxide (IrOₓ), or any combination thereof.

First ferroelectric dielectric 233 and second ferroelectric dielectric 243 can include ferroelectric materials including, but not limited to hafnium oxide (HfOₓ), zirconium oxide (ZrOₓ), titanium oxide (TiOₓ), aluminum oxide (AlOₓ), nickel oxide (NiOₓ), iron oxide (FeOₓ), or any combination thereof. In some embodiments, first ferroelectric dielectric 233 and second ferroelectric dielectric 243 can be doped with Si or other materials.

Plateline 251 can be electrically connected to a plateline driver from which a write voltage or a ground voltage can be driven to plateline 251.

It is noted that the x and y axes are included in FIG. 2A to illustrate two orthogonal directions in the wafer plane. It is noted that the z-axis is also included in FIG. 2B to further illustrate an orthogonal direction to the lateral surface of the substrate. That is, the substrate of ferroelectric memory cell 200 includes two lateral surfaces extending laterally in the x-y plane: a top surface on the front side of the wafer, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of a semiconductor device (e.g., ferroelectric memory cell 200) is determined relative to the substrate of the semiconductor device in the z-direction (the vertical direction perpendicular to the x-y plane) when the substrate is positioned in the lowest plane of the memory device in the z-direction. The same notion for describing the spatial relationships is applied throughout the present disclosure.

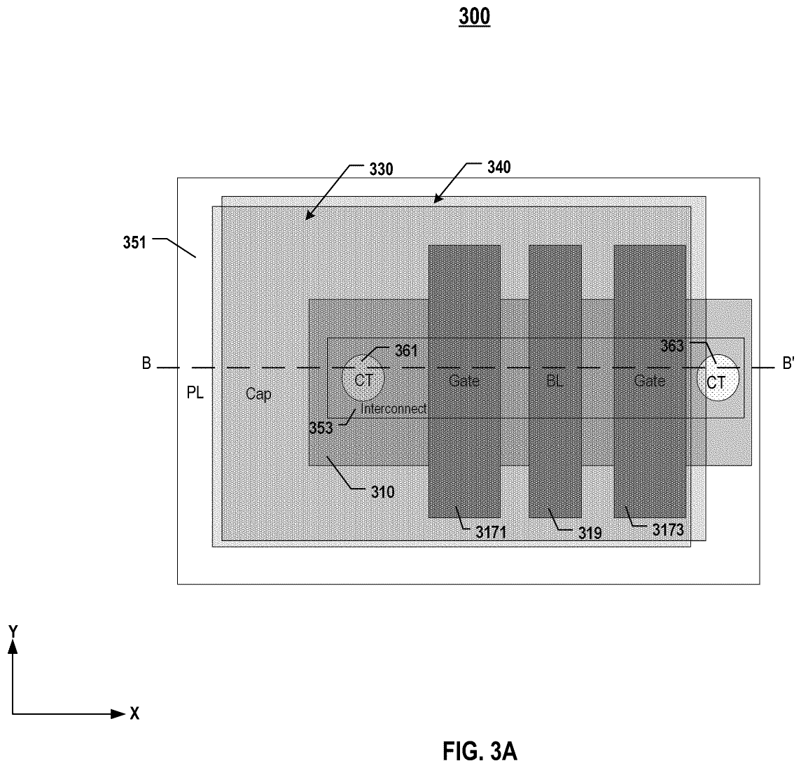

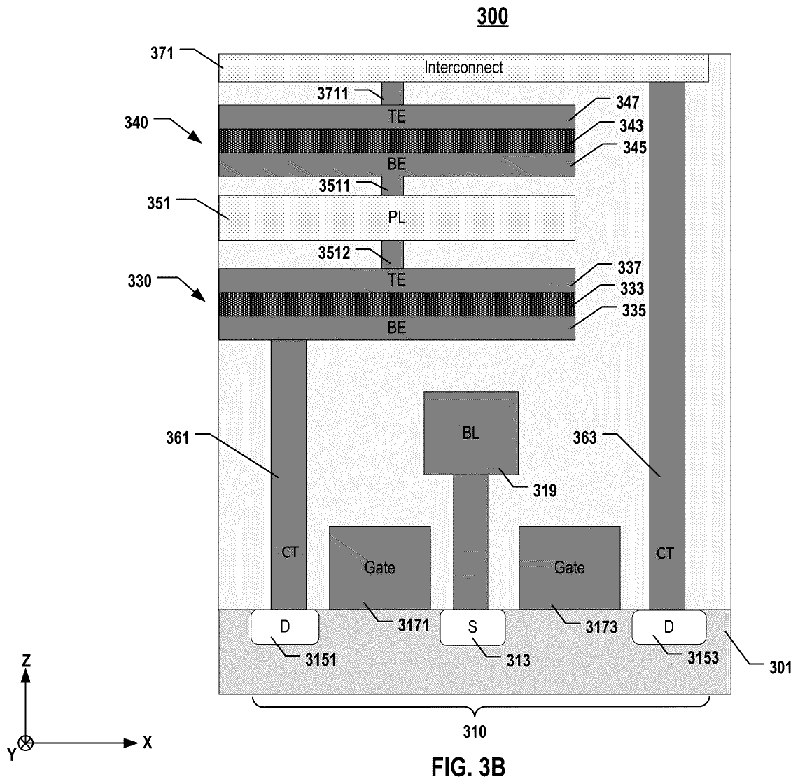

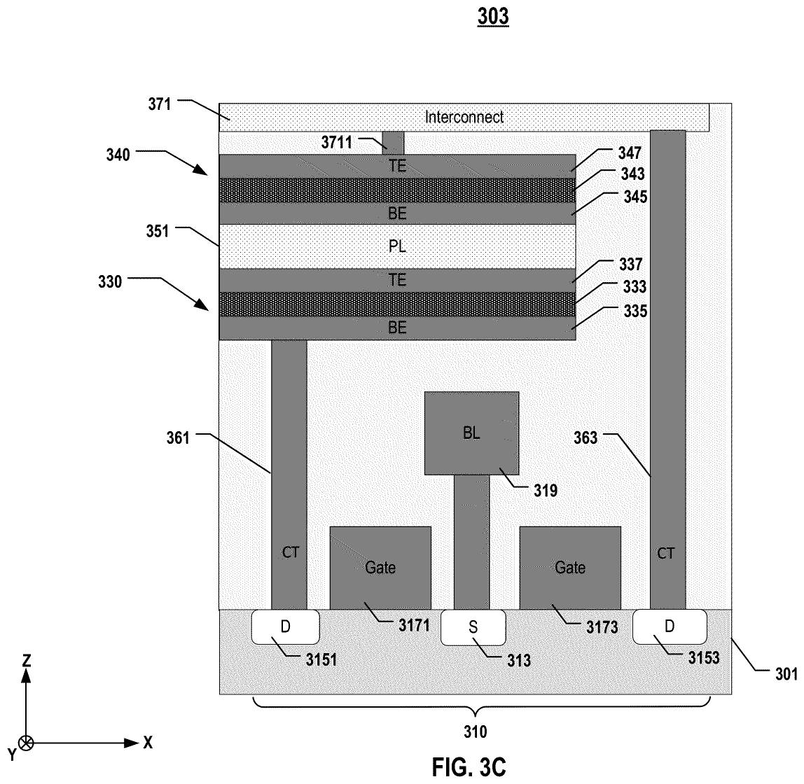

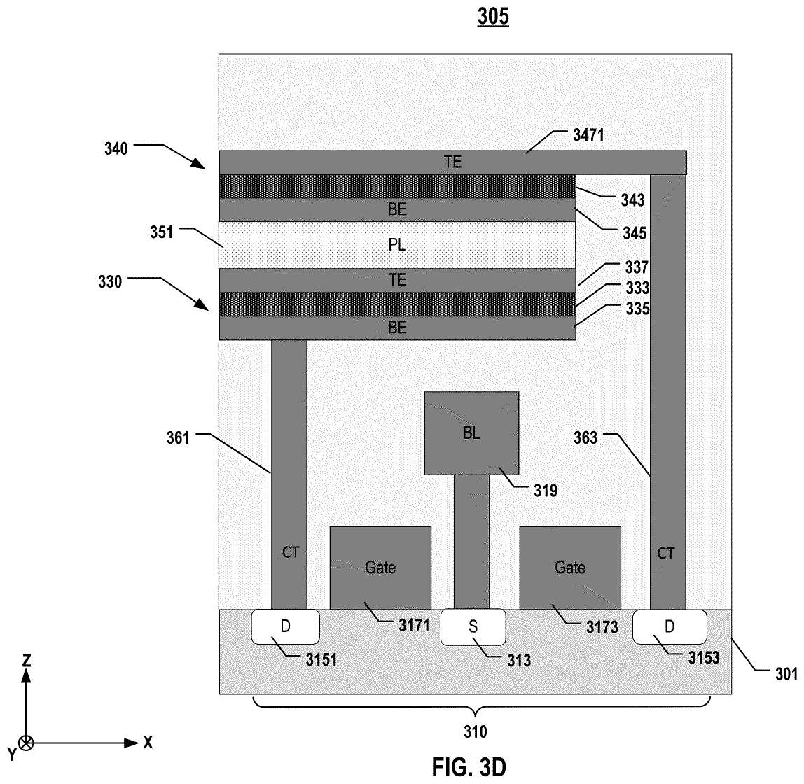

FIG. 3A illustrates a plan view of a ferroelectric memory cell 300, according to some aspects of the present disclosure, and FIG. 3B illustrates a side view of a cross-section of ferroelectric memory cell 300 along a BB′ direction as in FIG. 3A. As shown in FIGS. 3A and 3B, ferroelectric memory cell 300 includes a transistor pair 310 having a common source region 313 in a substrate 301, a first gate structure 3171 and a second gate structure 3173 on substrate 301, and a first drain region 3151 and a second drain region 3153 in substrate 301. Ferroelectric memory cell 300 may further include a common bit line 319 formed on and electrically connected to common source region 313, a first word line included in first gate structure 3171 or electrically connected to first gate structure 3171, a second word line included in second gate structure 3173 or electrically connected to second gate structure 3173, a first ferroelectric capacitor 330 formed on and electrically connected to first drain region 3151 via a first contact 361, a plateline 351 formed on and electrically connected to first ferroelectric capacitor 330, a second ferroelectric capacitor 340 formed on and electrically connected to plateline 351, an interconnect layer 371 formed on and electrically connected to second ferroelectric capacitor 340, and interconnect layer 371 is electrically connected to second drain region 3153 via a second contact 363. That is, plateline 351 is formed and electrically connected between first ferroelectric capacitor 330 and second ferroelectric capacitor 340. And interconnect layer 371 is electrically connected between second ferroelectric capacitor 340 and second drain region 3153. First ferroelectric capacitor 330 includes a first top electrode 337, a first bottom electrode 335, and a first ferroelectric dielectric 333 between first top electrode 337 and first bottom electrode 335. Second ferroelectric capacitor 340 includes a second top electrode 347, a second bottom electrode 345, and a second ferroelectric dielectric 343 between second top electrode 347 and second bottom electrode 345. In some embodiments, first ferroelectric capacitor 330 and second ferroelectric capacitor 340 may have the same area size. As shown in the plan view of ferroelectric memory cell 300 in FIG. 3A, the two ferroelectric capacitors (e.g., 330 and 340) are stacked and the entire chip size is reduced by almost 50%. The density of the ferroelectric memory cell is therefore increased significantly. In some embodiment, the two ferroelectric capacitors (e.g., 330 and 340) can be in align with each other in a vertical direction (e.g., z-direction). In some embodiment, the two ferroelectric capacitors (e.g., 330 and 340) can be staggered arranged.

Substrate 301 may include silicon (e.g., single crystalline silicon), silicon germanium (SiGe), gallium arsenide (GaAs), germanium (Ge), silicon on insulator (SOI), or any other suitable materials. In some embodiments, substrate 301 is p-doped or includes a p-doped region surrounding common source region 313, first drain region 3151, and second drain region 3153. In some embodiments, common source region 313, first drain region 3151, and second drain region 3153 are n-doped regions. Each of first gate structure 3171 and second gate structure 3173 may include a respective gate dielectric on substrate 301 and a respective gate electrode on the gate dielectric.

Common bit line 319 (or, in some embodiments, a first bit line and a second bit line), first and second word lines 3171 and 3173, first contact 361, second contact 363, plateline 351, and interconnect layer 371 can include conductive materials including, but not limited to, tungsten (W), cobalt (Co), copper (Cu), aluminum (Al), polysilicon, doped silicon, silicide, carbon, or any combination thereof. In some embodiments, each of common bit line 319, first and second word lines 3171 and 3173, plateline 351, and interconnect layer 371 includes a metal, such as tungsten. In some embodiments, plateline 351 may include carbon.

First top electrode 337, first bottom electrode 335, second top electrode 347, and second bottom electrode 345 can include conductive materials including, but not limited to, titanium nitride (TiN), titanium silicon nitride (TiSiNₓ), titanium aluminum nitride (TiAlNₓ), titanium carbon nitride (TiCNₓ), tantalum nitride (TaNₓ), tantalum silicon nitride (TaSiNₓ), tantalum aluminum nitride (TaAlNₓ), tungsten nitride (WNₓ), tungsten silicide (WSiₓ), tungsten carbon nitride (WCNₓ), ruthenium (Ru), ruthenium oxide (RuOₓ), iridium (Jr), doped polysilicon, transparent conductive oxides (TCO), or iridium oxide (IrOₓ), or any combination thereof.

First ferroelectric dielectric 333 and second ferroelectric dielectric 343 can include ferroelectric materials including, but not limited to hafnium oxide (HfOₓ), zirconium oxide (ZrOₓ), titanium oxide (TiOₓ), aluminum oxide (AlOₓ), nickel oxide (NiOₓ), iron oxide (FeOₓ), or any combination thereof. In some embodiments, first ferroelectric dielectric 333 and second ferroelectric dielectric 343 can be doped with Si or other materials.

In some embodiments, plateline 351 and first ferroelectric capacitor 330, and plateline 351 and second ferroelectric capacitor 340 are electrically connected through a first contact via 3511 and a second contact via 3512, respectively. Similarly, interconnect layer 371 and second ferroelectric capacitor 340 are electrically connected through a third contact via 3711. Plateline 351 can be electrically connected to a plateline driver (not shown) from which a write voltage or a ground voltage can be driven to plateline 351.

FIG. 3C illustrates a side view of a cross-section of an exemplary ferroelectric memory cell 303, according to some aspects of the present disclosure. Ferroelectric memory cell 303 is similar to ferroelectric memory cell 300 except that plateline 351 is directly contacting first ferroelectric capacitor 330 and second ferroelectric capacitor 340 rather than connecting through contact vias. This may simplify the fabrication process and reduce the fabrication cost.

FIG. 3D illustrates a side view of a cross-section of an exemplary ferroelectric memory cell 305, according to some aspects of the present disclosure. Ferroelectric memory cell 305 is similar to ferroelectric memory cell 303 except that there is no interconnect layer 371 and third contact via 3711 connected between interconnect layer 371 and second ferroelectric capacitor 340. Instead, an extended top electrode 3471 of second ferroelectric capacitor 340 is in contact with second contact 363 and electrically connected between second ferroelectric dielectric 343 and second contact 363. This may further simplify the fabrication process and reduce the fabrication cost.

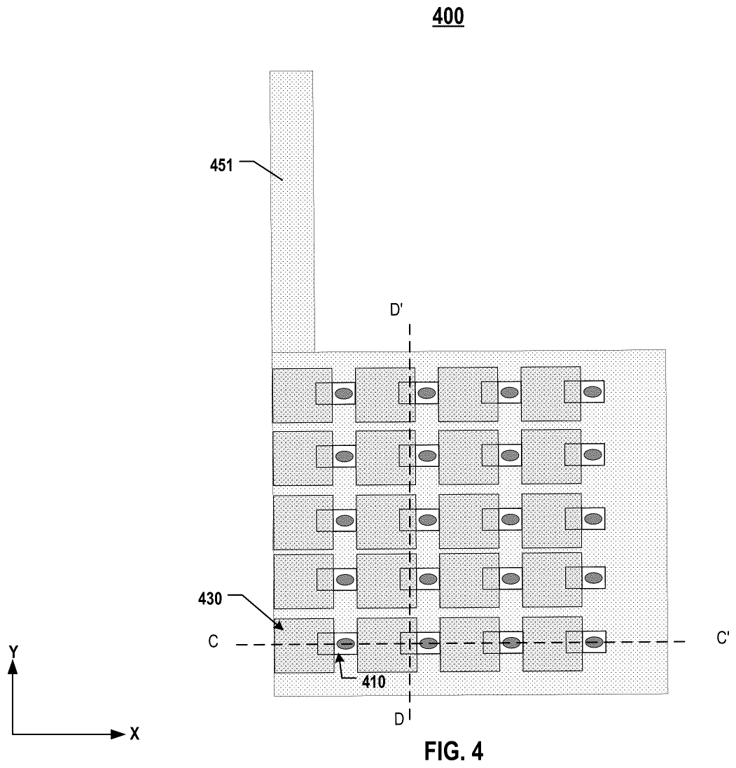

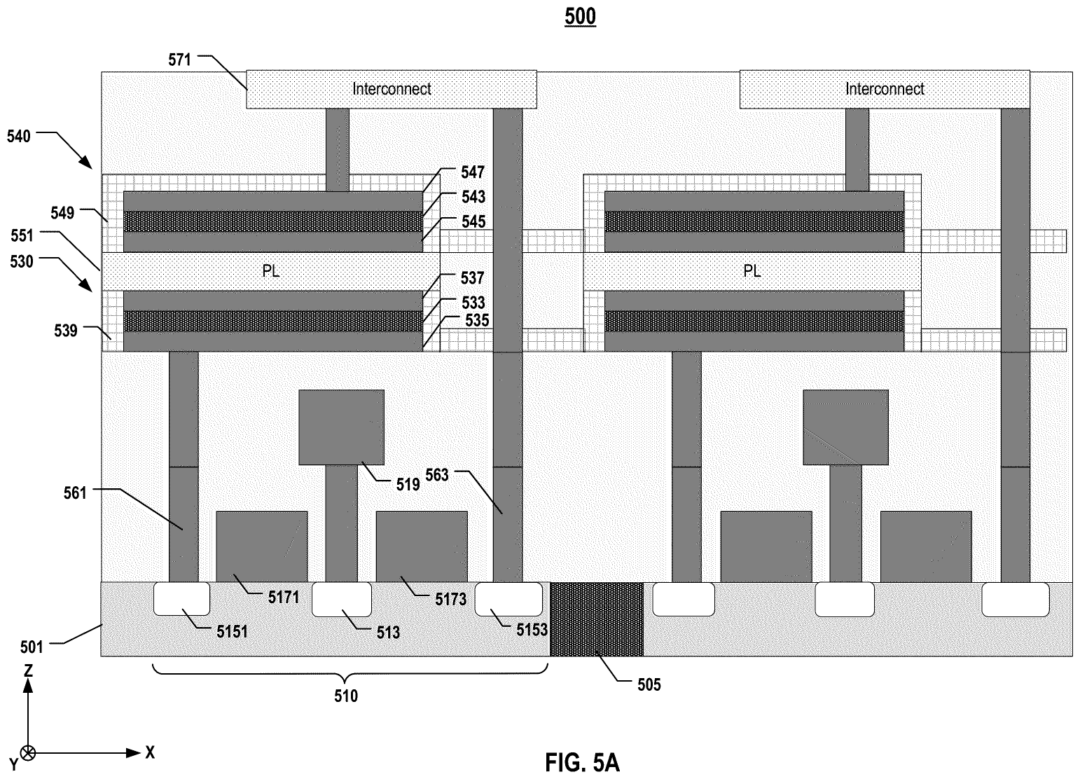

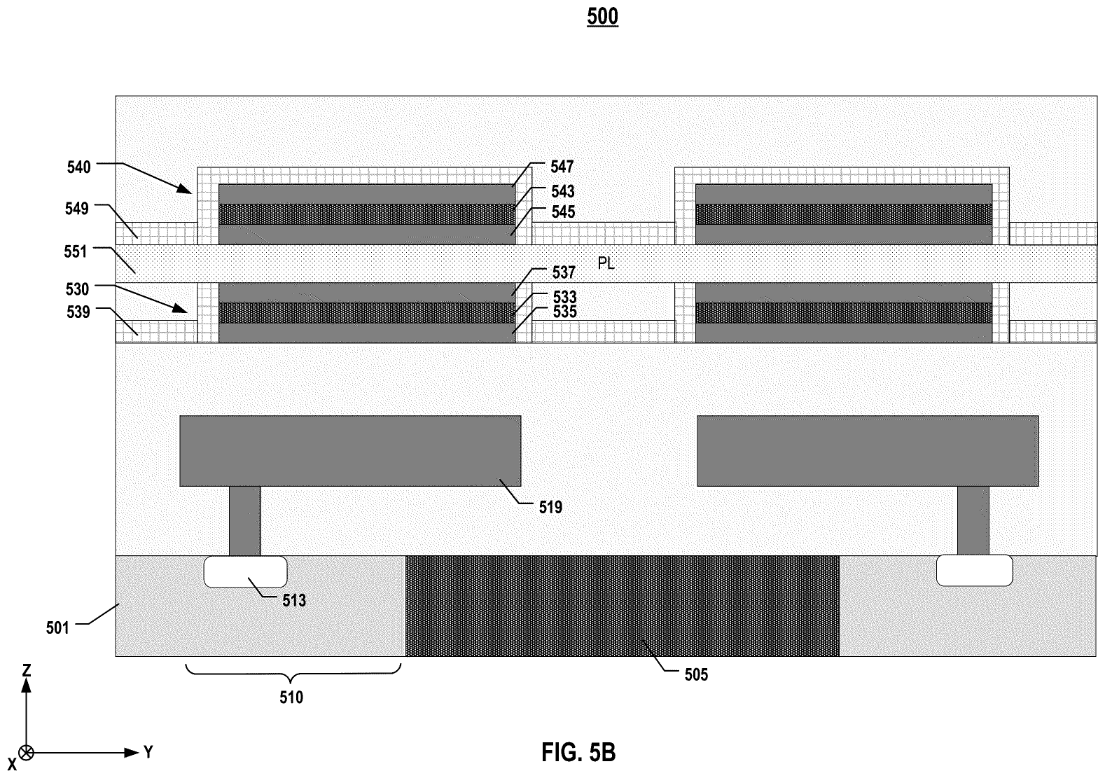

FIG. 4 illustrates a plan view of a ferroelectric memory device 400, according to some aspects of the present disclosure, FIG. 5A illustrates a side view of a cross-section of a part of ferroelectric memory device 400 along CC′ direction in FIG. 4, and FIG. 5B illustrates another side view of a cross-section of a part of ferroelectric memory device 400 along DD′ direction in FIG. 4, according to some aspects of the present disclosure. As shown in FIG. 4, ferroelectric memory device 400 includes multiple stacked ferroelectric capacitors (e.g., a ferroelectric capacitor 430) arranged in a 2D array, and transistors (e.g., a transistor pair 410) each partially covered by respective ferroelectric capacitors. Ferroelectric memory device 400 further includes a plateline 451 formed between ferroelectric capacitors and extending in a lateral direction (e.g., both x- and y-directions). The plateline 451 may include a mesh pattern such that an interconnect layer (not shown) may be connected between the top ferroelectric capacitor (not shown) and the transistors through vias (e.g., the contacts) that penetrate the mesh pattern of plateline 451 in a vertical direction (e.g., z-direction). In some embodiments, plateline 451 can be shared among ferroelectric capacitors of different ferroelectric memory cells laterally. In some embodiments, as shown in FIG. 4, plateline 451 may include an extended portion that can be used as a routing structure or connected to a routing structure. The routing structure may then be electrically connected to a plateline driver such that a write voltage can be introduced into the ferroelectric memory cells by the plateline driver. In some embodiments, ferroelectric memory device 400 in FIG. 4 may include multiple ferroelectric memory cells 300 in FIG. 3A arranged in the 2D array.

FIG. 5A shows a ferroelectric memory device 500 (e.g., corresponding to parts of ferroelectric memory device 400) include two ferroelectric memory cells (e.g., two ferroelectric memory cells 300) that are separated by an isolation trench 505 extending along the y-direction. Since there are two ferroelectric memory cells, each of which can store 2 bits, it can store 4 bits in ferroelectric memory device 500.

Ferroelectric memory device 500 includes two ferroelectric memory cells. Each ferroelectric cell includes a transistor pair 510 having a common source region 513 in a substrate 501, a first gate structure 5171 and a second gate structure 5173 on substrate 501, and a first drain region 5151 and a second drain region 5153 in substrate 501. Each ferroelectric memory cell of ferroelectric memory device 500 may further include a common bit line 519 formed on and electrically connected to common source region 513, a first word line included in first gate structure 5171 or electrically connected to first gate structure 5171, a second word line included in second gate structure 5173 or electrically connected to second gate structure 5173, a first ferroelectric capacitor 530 formed on and electrically connected to first drain region 5151 via a first contact 561, a plateline 551 formed on and electrically connected to first ferroelectric capacitor 530, a second ferroelectric capacitor 540 formed on and electrically connected to plateline 551, and an interconnect layer 571 formed on and electrically connected to second ferroelectric capacitor 540. Interconnect layer 571 is electrically connected to second drain region 5153 via a second contact 563. That is, plateline 551 is formed and electrically connected between first ferroelectric capacitor 530 and second ferroelectric capacitor 540. And interconnect layer 571 is electrically connected between second ferroelectric capacitor 540 and second drain region 5153. First ferroelectric capacitor 530 includes a first top electrode 537, a first bottom electrode 535, a first ferroelectric dielectric 533 between first top electrode 537 and first bottom electrode 535, and a first blocking layer 539 formed on at least a sidewall of first ferroelectric capacitor 530. Second ferroelectric capacitor 540 includes a second top electrode 547, a second bottom electrode 545, a second ferroelectric dielectric 543 between second top electrode 547 and second bottom electrode 545, and a second blocking layer 549 formed on at least a sidewall of second ferroelectric capacitor 540. In some embodiments, each of first blocking layer 539 and second blocking layer 549 may also be formed on a top surface or a bottom surface of first ferroelectric capacitor 530 and second ferroelectric capacitor 540 and leave a via in each surface for electrical connection. In some embodiments, plateline 551 may be formed on and in contact with first blocking layer 539 and second blocking layer 549 such that the plateline 551 may not be in contact with the sidewall of ferroelectric capacitors and prevent a leakage path formed therebetween. In some embodiments, plateline 551 may be only formed on a top surface of first ferroelectric capacitor 530 and may not be formed on first blocking layer 539 such that a sidewall of plateline 551 are in align with that of first ferroelectric capacitor 530 and that of second ferroelectric capacitor 540. In some embodiments, first ferroelectric capacitor 530 and second ferroelectric capacitor 540 may have the same area size.

FIG. 5B illustrates another side view of a cross-section of a part of ferroelectric memory device 400 along DD′ direction in FIG. 4, according to some aspects of the present disclosure. As shown in FIG. 5B, ferroelectric memory cells of ferroelectric memory device 400 are also separated by isolation trench 505 extending in the x-direction. And blocking layers (e.g., 539 and 549) are formed in four sides of ferroelectric capacitors (e.g., 530 and 540).

Substrate 501 may include silicon (e.g., single crystalline silicon), silicon germanium (SiGe), gallium arsenide (GaAs), germanium (Ge), silicon on insulator (SOI), or any other suitable materials. In some embodiments, substrate 501 is p-doped or includes a p-doped region surrounding common source region 513, first drain region 5151, and second drain region 5153. In some embodiments, common source region 513, first drain region 5151, and second drain region 5153 are n-doped regions. Each of first gate structure 5171 and second gate structure 5173 may include a respective gate dielectric on substrate 501 and a respective gate electrode on the gate dielectric.

Common bit line 519, first and second word lines 5171 and 5173, first contact 561, second contact 563, plateline 551, and interconnect layer 571 can include conductive materials including, but not limited to, tungsten (W), cobalt (Co), copper (Cu), aluminum (Al), polysilicon, doped silicon, silicide, or any combination thereof. In some embodiments, each of common bit line 519, first and second word lines 5171 and 5173, plateline 551, and interconnect layer 571 includes a metal, such as tungsten. In some embodiments, plateline 551 may include carbon.

First top electrode 537, first bottom electrode 535, second top electrode 547, and second bottom electrode 545 can include conductive materials including, but not limited to, titanium nitride (TiN), titanium silicon nitride (TiSiNₓ), titanium aluminum nitride (TiAlNₓ), titanium carbon nitride (TiCNₓ), tantalum nitride (TaNₓ), tantalum silicon nitride (TaSiNₓ), tantalum aluminum nitride (TaAlNₓ), tungsten nitride (WNₓ), tungsten silicide (WSiₓ), tungsten carbon nitride (WCNₓ), ruthenium (Ru), ruthenium oxide (RuOₓ), iridium (Jr), doped polysilicon, transparent conductive oxides (TCO), or iridium oxide (IrOₓ), or any combination thereof.

First ferroelectric dielectric 533 and second ferroelectric dielectric 543 can include ferroelectric materials including, but not limited to hafnium oxide (HfOₓ), zirconium oxide (ZrOₓ), titanium oxide (TiOₓ), aluminum oxide (AlOₓ), nickel oxide (NiOₓ), iron oxide (FeOₓ), or any combination thereof. In some embodiments, first ferroelectric dielectric 533 and second ferroelectric dielectric 543 can be doped with Si or other materials.

In some embodiments, plateline 551 and first ferroelectric capacitor 530, and/or plateline 551 and second ferroelectric capacitor 540 can be electrically connected through a contact via (not shown) rather than directly contacting first ferroelectric capacitor 530 or second ferroelectric capacitor 540. Similarly, interconnect layer 571 and second ferroelectric capacitor 540 are electrically connected through a contact via (not shown) rather than directly contacting second ferroelectric capacitor 540. Plateline 551 can be electrically connected to a plateline driver (not shown) from which a write voltage or a ground voltage can be driven to plateline 551.

First blocking layer 539 and second blocking layer 549 can include a high-k dielectric material including, but not limited to, AlOₓ, ZrOₓ, YOₓ, TiOₓ, SiNx, or any combination thereof. Therefore, first blocking layer 539 and second blocking layer 549 can be configured to prevent and protect first ferroelectric dielectric 533 and second ferroelectric dielectric 543 from unwanted moistures or dopants, such as H or O. In some embodiments, first blocking layer 539 and second blocking layer 549 can be configured to act as a stress reducing layer which reduces the stress of first ferroelectric capacitor 530 and second ferroelectric capacitor 540.

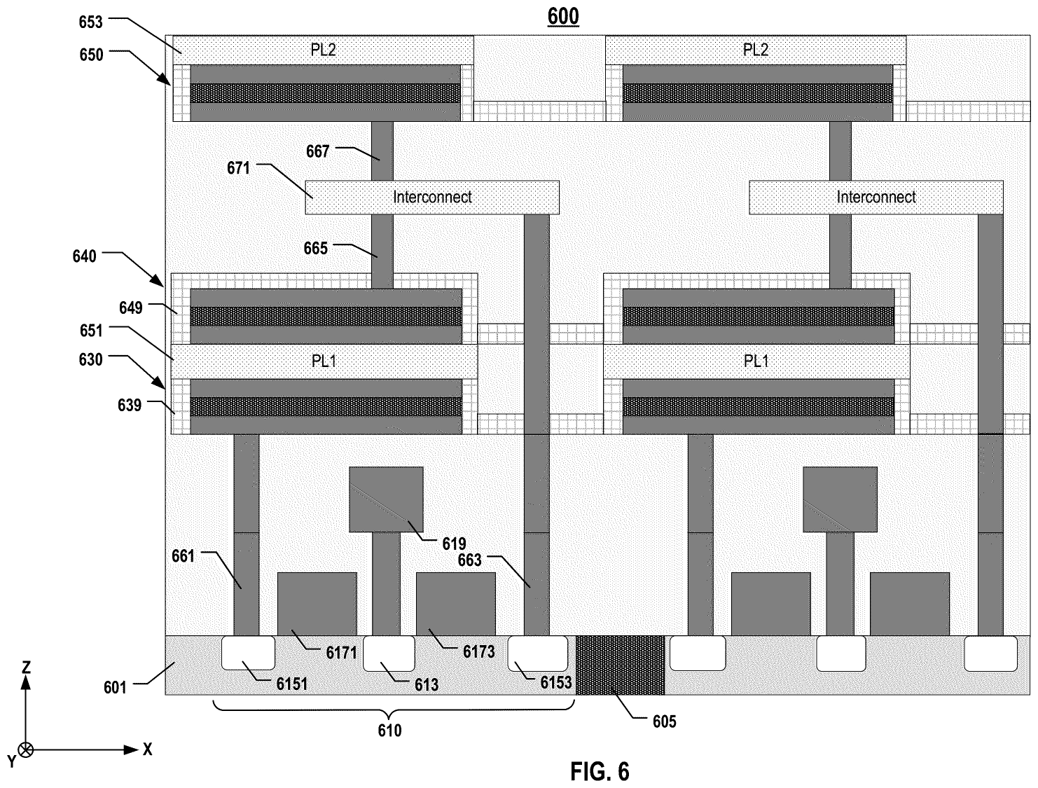

FIG. 6 illustrates a side view of a cross-section of an exemplary ferroelectric memory device 600, according to some aspects of the present disclosure. Compared to ferroelectric memory device 500 in FIG. 5A, ferroelectric memory device 600 includes a third ferroelectric capacitor 650 formed on interconnect layer 571 (e.g., corresponding to interconnect layer 671 in FIG. 6). Furthermore, ferroelectric memory device 600 also includes a second plateline 653 on third ferroelectric capacitor 650. Second plateline 653 is configured to drive a write voltage into third ferroelectric capacitor 650. This allows ferroelectric memory device 600 to be able to store 6 bits, and the ferroelectric capacitors can be driven by two platelines.

Ferroelectric memory device 600 includes two ferroelectric memory cells separated by an isolation trench 605. Each ferroelectric cell includes a transistor pair 610 having a common source region 613 in a substrate 601, a first gate structure 6171 and a second gate structure 6173 on substrate 601, and a first drain region 6151 and a second drain region 6153 in substrate 601. Each ferroelectric memory cell of ferroelectric memory device 600 may further include a common bit line 619 formed on and electrically connected to common source region 613, a first word line included in first gate structure 6171 or electrically connected to first gate structure 6171, a second word line included in second gate structure 6173 or electrically connected to second gate structure 6173, a first ferroelectric capacitor 630 formed on and electrically connected to first drain region 6151 via a first contact 661, a first plateline 651 formed on and electrically connected to first ferroelectric capacitor 630, a second ferroelectric capacitor 640 formed on and electrically connected to first plateline 651, an interconnect layer 671 formed on and electrically connected to second ferroelectric capacitor 640 via a third contact 665, a third ferroelectric capacitor 650 formed on and electrically connected to second interconnect layer 671 via a fourth contact 667, and a second plateline 653 formed on and electrically connected to third ferroelectric capacitor 650. Interconnect layer 671 is electrically connected to second drain region 6153 via a second contact 663. That is, first plateline 651 is formed and electrically connected between first ferroelectric capacitor 630 and second ferroelectric capacitor 640. And interconnect layer 671 is electrically connected between second ferroelectric capacitor 640 and second drain region 6153, and between third ferroelectric capacitor 650 and second drain region 6153. Each of first ferroelectric capacitor 630, second ferroelectric capacitor 640, and third ferroelectric capacitor 650 includes a respective top electrode, a respective bottom electrode, a respective ferroelectric dielectric between the top electrode and the bottom electrode, and a respective blocking layer formed on at least a sidewall of first ferroelectric capacitor 630, second ferroelectric capacitor 640, and third ferroelectric capacitor 650. In some embodiments, each of the blocking layers may also be formed on a top surface or a bottom surface of first ferroelectric capacitor 630, second ferroelectric capacitor 640, and third ferroelectric capacitor 650 and leave a via in each surface for electrical connection to the contacts, platelines, or interconnect layers. The structures, functions, and materials of the same or similar components that have been described above with respect to ferroelectric memory devices 300, 400, or 500 are not repeated for ease of description.

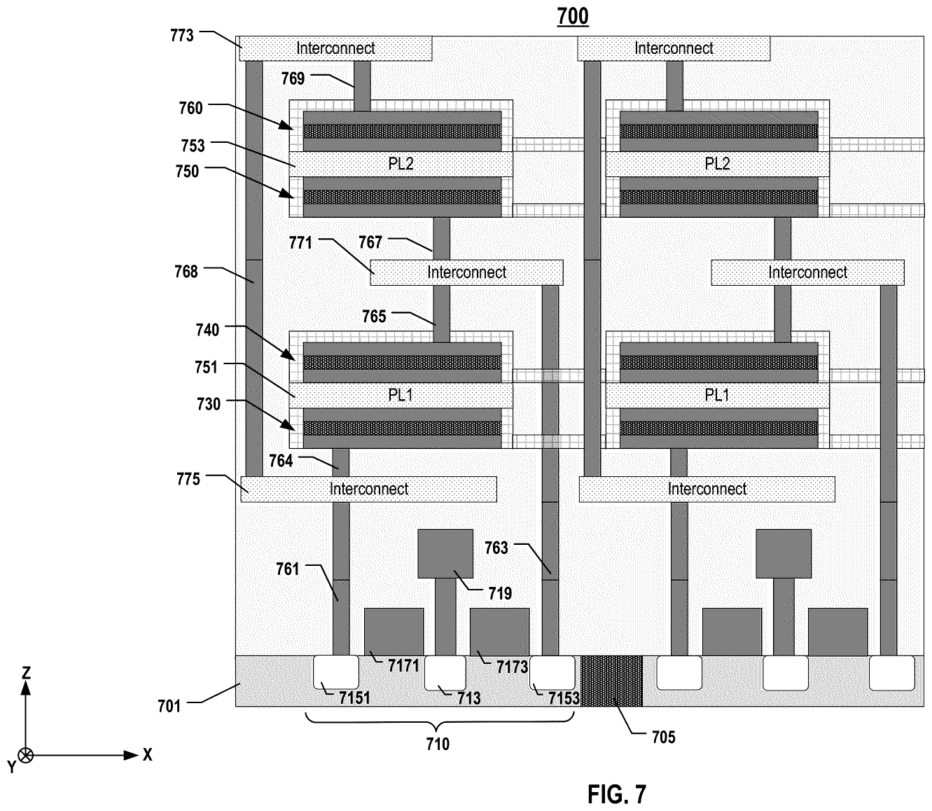

FIG. 7 illustrates a side view of a cross-section of an exemplary ferroelectric memory device 700, according to some aspects of the present disclosure. Compared to ferroelectric memory device 600 in FIG. 6, ferroelectric memory device 700 includes a fourth ferroelectric capacitor 760 formed on second plateline 653 (e.g., corresponding to second plateline 753 in FIG. 7). Furthermore, ferroelectric memory device 700 also includes a second interconnect layer 773 formed on and electrically connected to fourth ferroelectric capacitor 760, and a third plateline 761 connected to second interconnect layer 773. Therefore, this allows ferroelectric memory device 700 to be able to store 8 bits, and the four ferroelectric capacitors can be driven by three platelines.

Ferroelectric memory device 700 includes two ferroelectric memory cells separated by an isolation trench 705. Each ferroelectric cell includes a transistor pair 710 having a common source region 713 in a substrate 701, a first gate structure 7171 and a second gate structure 7173 on substrate 701, and a first drain region 7151 and a second drain region 7153 in substrate 701. Each ferroelectric memory cell of ferroelectric memory device 700 may further include a common bit line 719 formed on and electrically connected to common source region 713, a first word line included in first gate structure 7171 or electrically connected to first gate structure 7171, a second word line included in second gate structure 7173 or electrically connected to second gate structure 7173, a first plateline 751 formed and electrically connected between a first ferroelectric capacitor 730 and a second ferroelectric capacitor 740, a second plateline 753 formed and electrically connected between a third ferroelectric capacitor 750 and a fourth ferroelectric capacitor 760, a third interconnect layer 775 formed and electrically connected between first drain region 7151 and fourth ferroelectric capacitor 760, a first interconnect layer 771 formed and electrically connected between second drain region 7153 and second ferroelectric capacitor 740, and between second drain region 7153 and third ferroelectric capacitor 750, and a second interconnect layer 773 formed and electrically connected between fourth ferroelectric capacitor 760 and third interconnect layer 775. Third interconnect layer 775 is connected to first drain region 7151 via a first contact 761, and connected to second interconnect layer 773 via sixth contact 768. Third interconnect layer 775 is further connected to first ferroelectric capacitor 730. First interconnect layer 771 is connected to second drain region 7153 via a second contact 763, connected to second ferroelectric capacitor 740 via a third contact 765, and connected to third ferroelectric capacitor 750 via a fourth contact 767. Second interconnect layer 773 is connected to fourth ferroelectric capacitor 760 via a fifth contact 769. Each of first ferroelectric capacitor 730, second ferroelectric capacitor 740, third ferroelectric capacitor 750, and fourth ferroelectric capacitor 760 includes a respective top electrode, a respective bottom electrode, a respective ferroelectric dielectric between the top electrode and the bottom electrode, and a respective blocking layer formed on at least a sidewall of first ferroelectric capacitor 730, second ferroelectric capacitor 740, third ferroelectric capacitor 750, and fourth ferroelectric capacitor 760. In some embodiments, each of the blocking layers may also be formed on a top surface or a bottom surface of first ferroelectric capacitor 730, second ferroelectric capacitor 740, third ferroelectric capacitor 750, and fourth ferroelectric capacitor 760, and leave a via in each surface for electrical connection to the contacts, platelines, or interconnect layers. The structures, functions, and materials of the same or similar components that have been described above with respect to ferroelectric memory devices 300, 400, 500, or 600 are not repeated for ease of description.

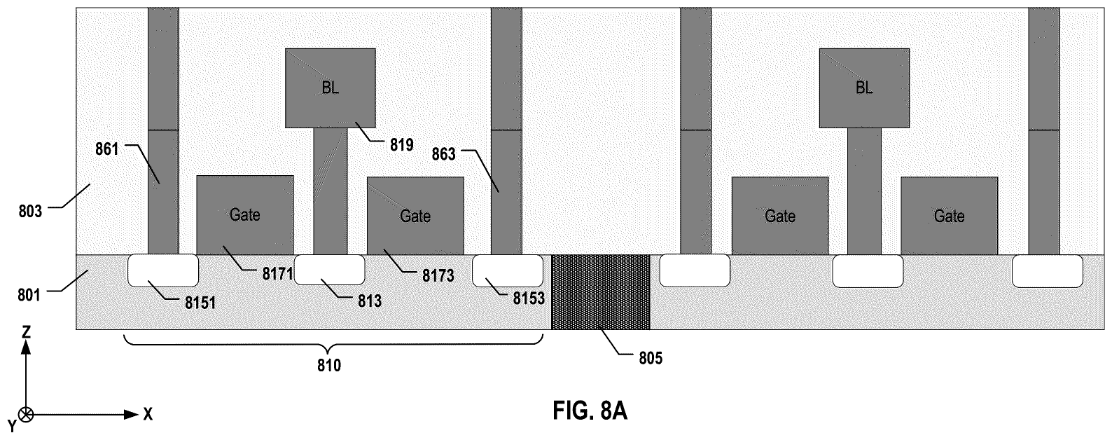

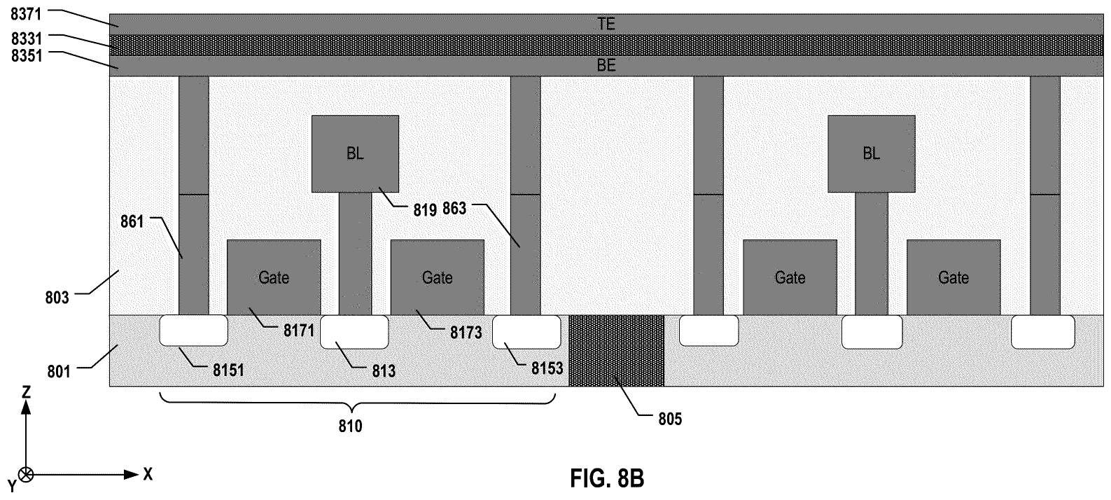

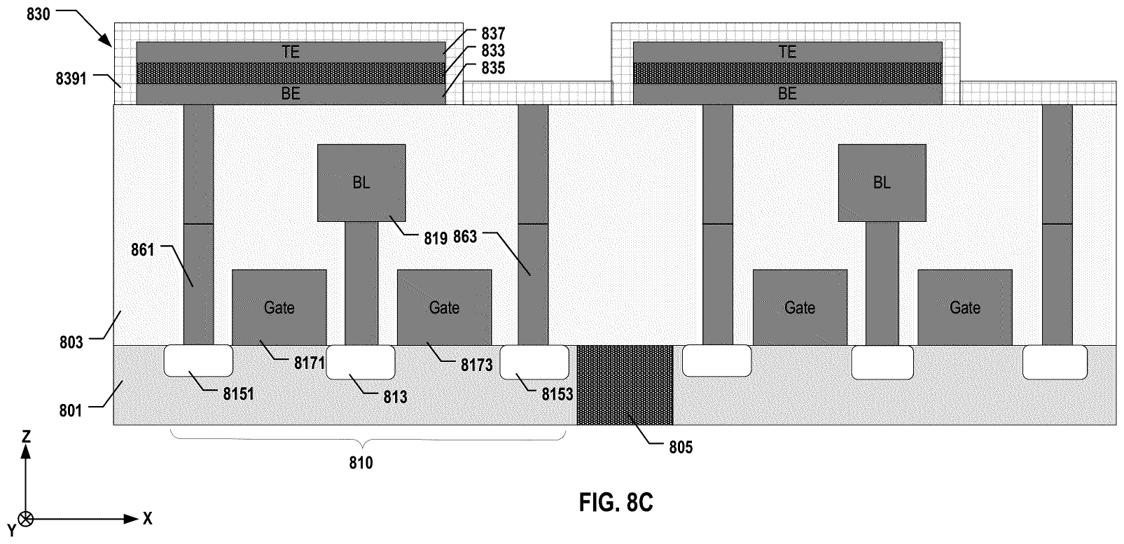

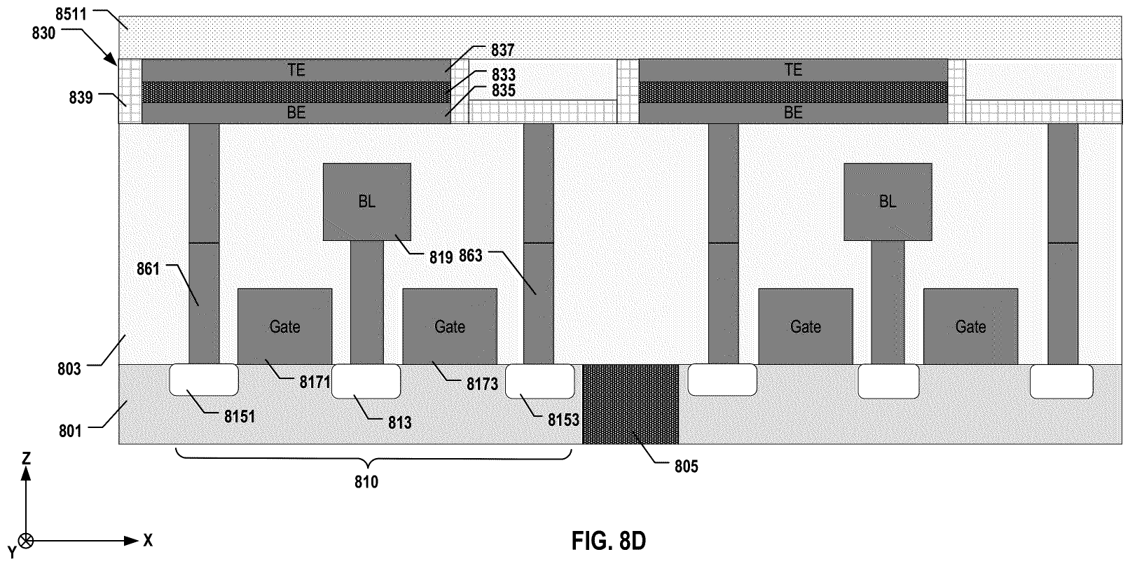

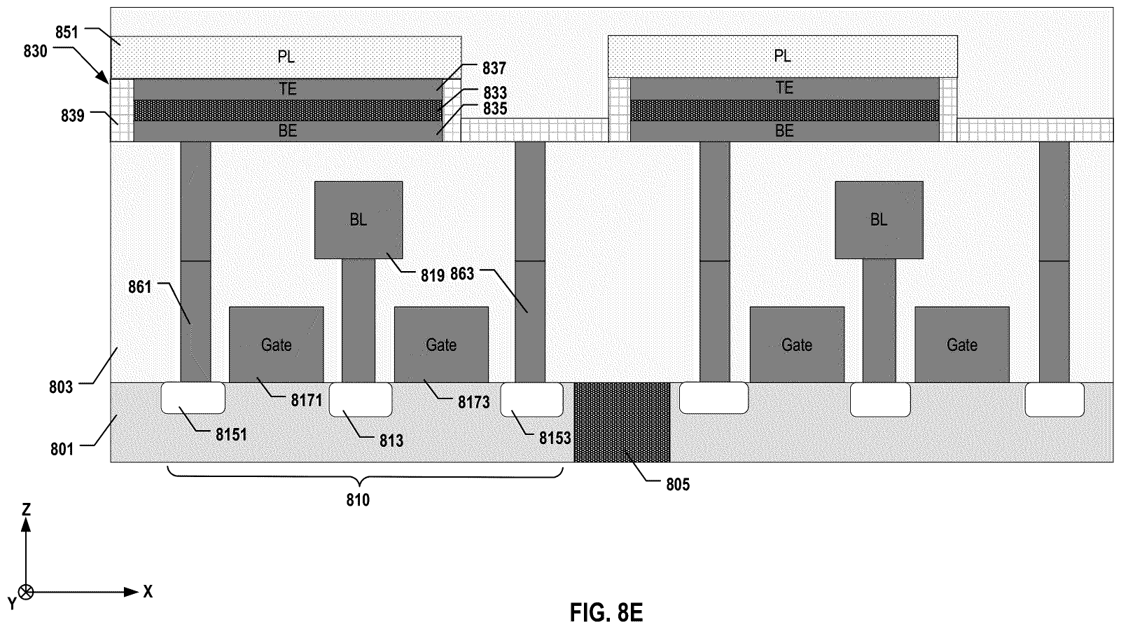

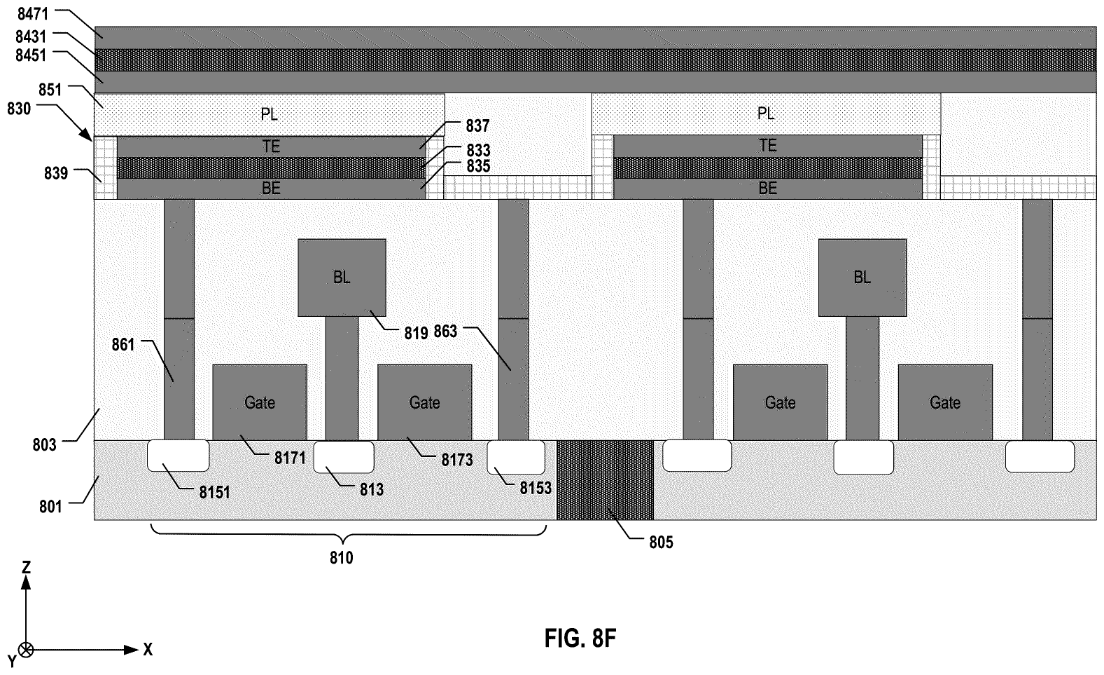

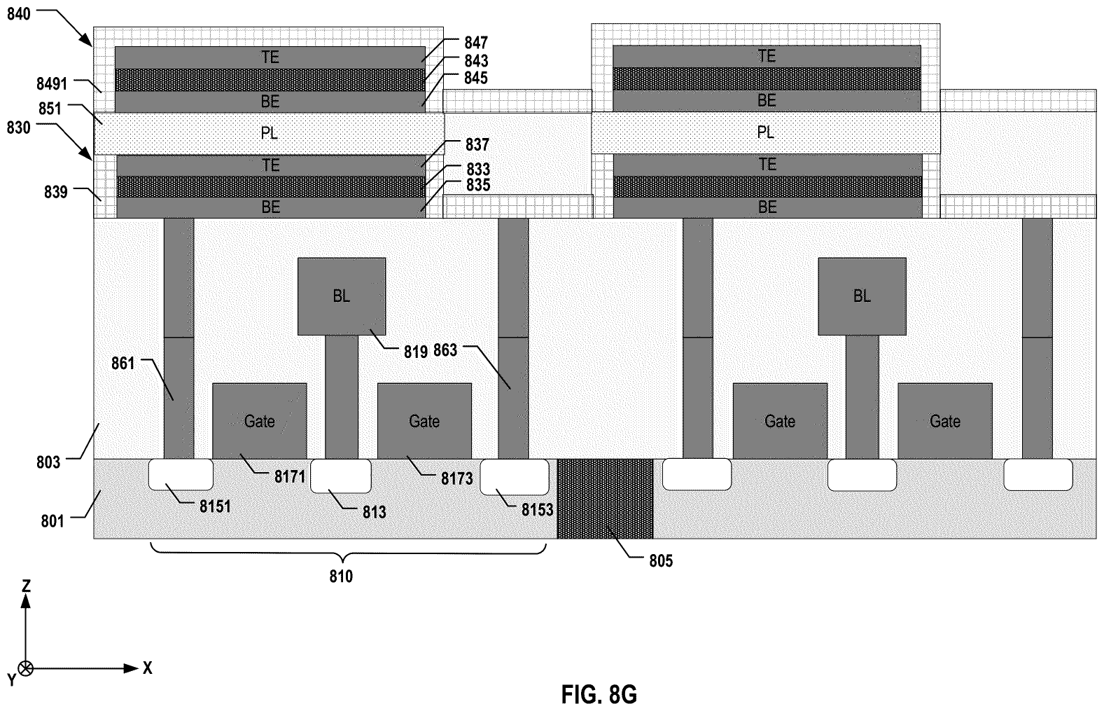

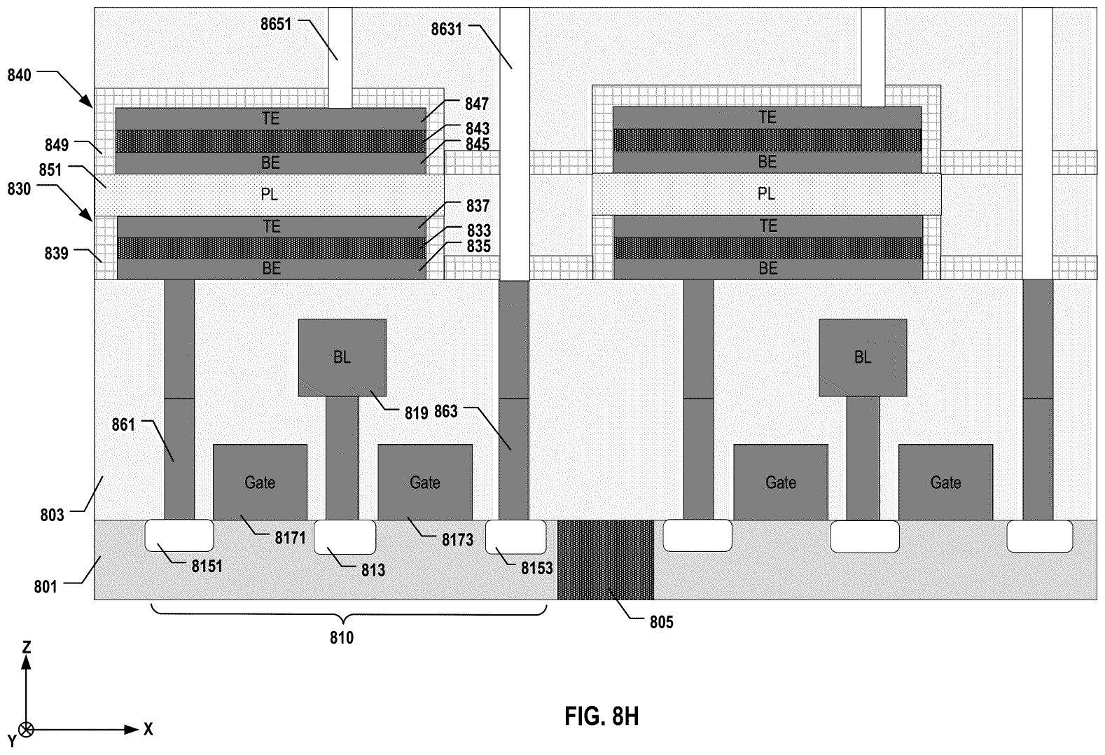

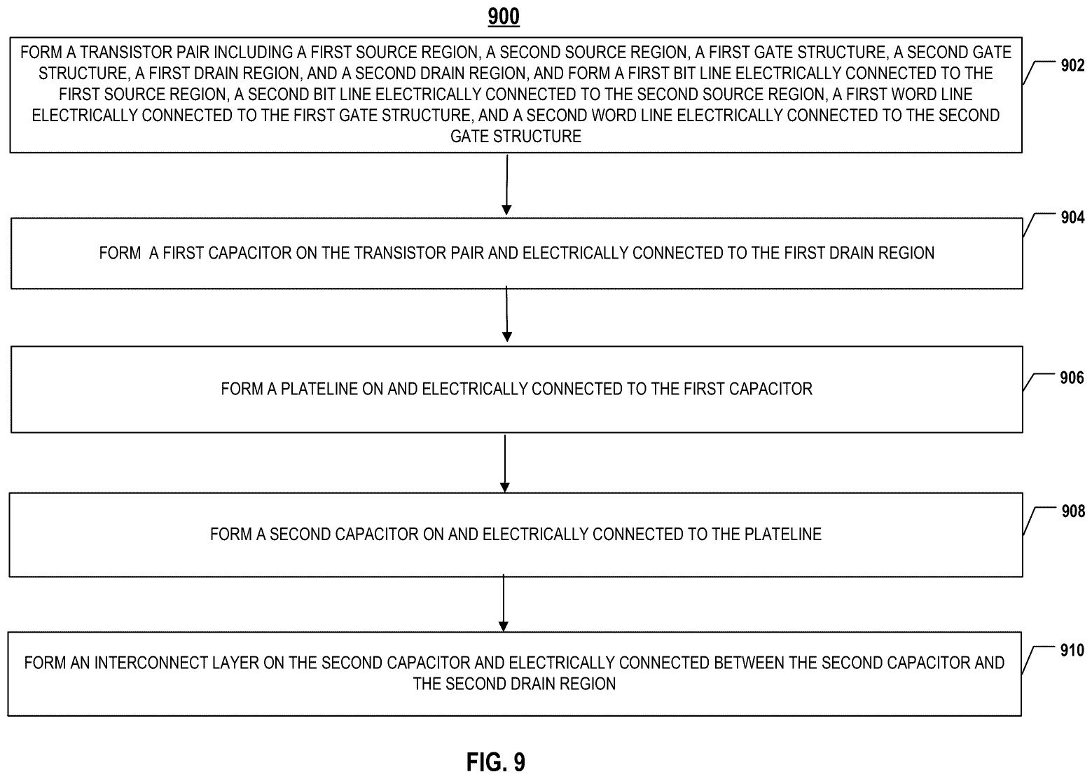

FIGS. 8A-8H illustrate a fabrication process for forming an exemplary ferroelectric memory device (e.g.), according to some aspects of the present disclosure. FIG. 9 illustrates a flowchart of a method for forming the exemplary ferroelectric memory device, according to some aspects of the present disclosure. Examples of the ferroelectric memory device depicted in FIGS. 8A-8H and 9 include ferroelectric memory device 500 depicted in FIG. 5A. FIGS. 8A-8H and 9 will be described together. It is understood that the fabrication processes shown in method 900 are not exhaustive and that other processes can be performed as well before, after, or between any of the illustrated processes. Further, some of the processes may be performed simultaneously, or in a different order than shown in FIG. 9.

Referring to FIG. 9, method 900 starts at process 902 in which a transistor pair including a common source region, a first gate structure, a second gate structure, a first drain region, and a second drain region is formed, and a common bit line electrically connected to the common source region, a first word line electrically connected to a first gate structure, and a second word line electrically connected to a second gate structure are formed. For example, as shown in FIG. 8A, a substrate 801 is provided, and an isolation trench 805 is formed extending in substrate 801 in the vertical direction (e.g., z-direction) to separate substrate 801 into two memory cell regions. A transistor pair 810 is formed in each of two memory cell regions. Transistor pair 810 includes a common source region 813, a first drain region 8151, and a second drain region 8153 formed in substrate 801. In some embodiments, common source region 813, first drain region 8151, and second drain region 8153 may be doped with n dopants, and substrate 801 may be doped with p dopants. A first gate structure 8171 is formed on substrate 801 and between common source region 813 and first drain region 8151, and a second gate structure 8173 is formed on substrate 801 and between common source region 813 and second drain region 8153. A first word line is formed on first drain region 8151, and a second word line is formed on second drain region 8153. A bit line 819 is formed on common source region 813. The forming of word lines and bit lines can be done by one or more thin film deposition processes including, but not limited to, chemical vapor deposition (CVD), physical vapor deposition (PVD), atomic layer deposition (ALD), or any combination thereof. Furthermore, in some embodiments, after depositing word lines and bit lines, an insulation layer 803, such as SiO₂, can be formed on substrate 801 covering the word lines and bit lines to protect transistor pair 810 from moisture or other contaminants. Later, a first contact 861 and a second contact 863 may be formed on the substrate and in contact with first drain region 8151 and second drain region 8153, respectively. To form contacts, an etching process including, but not limited to, dry etching, wet etching, or a combination thereof, can be performed to form through holes extending in insulation layer 803 until exposing first drain region 8151 and second drain region 8153. And first contact 861 and second contact 863 can be formed by a deposition process of, for example, conductive materials in the respective through holes.

Method 900 proceeds to process 904, as illustrated in FIG. 9 in which, a first ferroelectric capacitor on the transistor pair and electrically connected to the first drain region is formed. For example, as FIG. 8B, a first bottom electrode layer 8351, a first ferroelectric dielectric layer 8331, and a first top electrode layer 8371 are sequentially deposited on insulation layer 803, first contact 861, and second contact 863. The forming of first bottom electrode layer 8351, first ferroelectric dielectric layer 8331, and first top electrode layer 8371 can be done by one or more thin film deposition processes including, but not limited to, chemical vapor deposition (CVD), physical vapor deposition (PVD), atomic layer deposition (ALD), or any combination thereof. Next, as shown in FIG. 8C, an etching process can be applied upon first bottom electrode layer 8351, first ferroelectric dielectric layer 8331, and first top electrode layer 8371 to form first bottom electrode 835, first ferroelectric dielectric 833, and first top electrode 837. Therefore, first bottom electrode 835 is in contact with first contact 861. A first ferroelectric capacitor 830 including first bottom electrode 835, first ferroelectric dielectric 833, and first top electrode 837 is formed thereafter. In some embodiments, a first blocking sacrificial layer 8391 is conformally formed on insulation layer 803, sidewalls of first bottom electrode 835, first ferroelectric dielectric 833, and first top electrode 837, and a top surface of first top electrode 837. The forming of first blocking sacrificial layer 8391 can be done by one or more thin film deposition processes including, but not limited to, chemical vapor deposition (CVD), physical vapor deposition (PVD), atomic layer deposition (ALD), or any combination thereof.

Method 900 proceeds to process 906, as illustrated in FIG. 9 in which a plateline on the first capacitor and electrically connected to the first capacitor is formed. For example, as FIG. 8D, after forming first blocking sacrificial layer 8391, an etching process including, but not limited to, dry etching, wet etching, chemical mechanical polishing (CMP), or a combination thereof, can be performed to remove a top portion of first blocking sacrificial layer 8391 to form first blocking layer 839 covering sidewalls of first bottom electrode 835, first ferroelectric dielectric 833, and first top electrode 837, and exposing first top electrode 837. Next, a sacrificial plateline 8551 is deposited on first top electrode 837. Next, as shown in FIG. 8E, another etching process can be applied over sacrificial plateline 8551 to form a plateline 851 on and electrically connected to first top electrode 837. In some embodiments, another deposition process of insulation layer 803 can be applied to cover a top surface of plateline 851 and fill the gaps between platelines and ferroelectric capacitors of respective ferroelectric memory cells.

Method 900 proceeds to process 908, as illustrated in FIG. 9 in which a second ferroelectric capacitor on the plateline and electrically connected to the plateline is formed. For example, as FIG. 8F, after forming plateline 851 and also the regrowth of insulation layer 803 over plateline 851 as in FIG. 8E, an etching process including, but not limited to, dry etching, wet etching, chemical mechanical polishing (CMP), or a combination thereof, can be performed to remove a top portion of insulation layer 803 to expose plateline 851. Next, a second bottom electrode layer 8451, a second ferroelectric dielectric layer 8431, and a second top electrode layer 8471 are sequentially deposited on plateline 851 and a portion of insulation layer 803. The forming of second bottom electrode layer 8451, second ferroelectric dielectric layer 8431, and second top electrode layer 8471 can be done by one or more thin film deposition processes including, but not limited to, chemical vapor deposition (CVD), physical vapor deposition (PVD), atomic layer deposition (ALD), or any combination thereof. Next, as shown in FIG. 8G, an etching process can be applied upon second bottom electrode layer 8451, second ferroelectric dielectric layer 8431, and second top electrode layer 8471 to form a second bottom electrode 845, a second ferroelectric dielectric 843, and a second top electrode 847. Therefore, second bottom electrode 845 is in contact with plateline 851. A second ferroelectric capacitor 840 including second bottom electrode 845, second ferroelectric dielectric 843, and second top electrode 847 is formed on and electrically connected to plateline 851 thereafter. In some embodiments, a second blocking sacrificial layer 8491 is conformally formed on insulation layer 803, sidewalls of second bottom electrode 845, second ferroelectric dielectric 843, and second top electrode 847, and a top surface of second top electrode 847. The forming of second blocking sacrificial layer 8491 can be done by one or more thin film deposition processes including, but not limited to, chemical vapor deposition (CVD), physical vapor deposition (PVD), atomic layer deposition (ALD), or any combination thereof.

Method 900 proceeds to process 910, as illustrated in FIG. 9 in which an interconnect layer on the second ferroelectric capacitor and electrically connected between the second ferroelectric capacitor and the second drain region is formed. For example, as FIG. 8H, after forming second ferroelectric capacitor 840 over plateline 851 as in FIG. 8G, another deposition process of insulation layer 803 can be applied to cover a top surface of second ferroelectric capacitor 840 and fill the gaps between ferroelectric capacitors of respective ferroelectric memory cells. Next, an etching process including, but not limited to, dry etching, wet etching, chemical mechanical polishing (CMP), or a combination thereof, can be performed to form a first through hole 8651 exposing second top electrode 847, and a second through hole 8631 exposing second contact 863. After that, first through hole 8651 and second through hole 8631 are deposited and filled by a conductive material to form two contacts (not shown) electrically connected to second top electrode 847 and second contact 863. In some embodiments, second contact 863 may be formed in the same process rather than forming two separated contacts. In particular, second contact 863 may be formed by etching second through hole 8631 to expose second drain region 8153 and then filled second through hole 8631 with conductive material. Finally, an interconnect layer (e.g., interconnect layer 571 as in FIG. 5A) is deposited on the two contacts.

The foregoing description of the specific embodiments can be readily modified and/or adapted for various applications. Therefore, such adaptations and modifications are intended to be within the meaning and range of equivalents of the disclosed embodiments, based on the teaching and guidance presented herein.

The breadth and scope of the present disclosure should not be limited by any of the above-described exemplary embodiments, but should be defined only in accordance with the following claims and their equivalents.

What is claimed is:

1. A ferroelectric memory cell, comprising:
a transistor pair comprising a first source region, a second source region, a first gate structure, a second gate structure, a first drain region, and a second drain region;
a first ferroelectric capacitor formed on and electrically connected to the first drain region;
a first plateline formed on and electrically connected to the first ferroelectric capacitor; and
a second ferroelectric capacitor formed on and electrically connected to the first plateline, wherein the second ferroelectric capacitor is electrically connected to the second drain region.

2. The ferroelectric memory cell of claim 1, further comprising:
a first interconnect layer formed on the second ferroelectric capacitor and electrically connected between the second ferroelectric capacitor and the second drain region.

3. The ferroelectric memory cell of claim 1, wherein the first plateline comprises an extended portion which is configured to be a routing structure.

4. The ferroelectric memory cell of claim 1, wherein the first plateline comprises an extended portion connected to a routing structure.

5. The ferroelectric memory cell of claim 1, wherein the first plateline includes a mesh pattern.

6. The ferroelectric memory cell of claim 1, further comprising:
a first contact electrically connected between the first ferroelectric capacitor and the first drain region; and
a second contact electrically connected between the second ferroelectric capacitor and the second drain region.

7. The ferroelectric memory cell of claim 6, wherein the first ferroelectric capacitor comprises a first bottom electrode, a first ferroelectric dielectric on the first bottom electrode, and a first top electrode on the first ferroelectric dielectric, and wherein the second ferroelectric capacitor comprises a second bottom electrode, a second ferroelectric dielectric on the second bottom electrode, and a second top electrode on the second ferroelectric dielectric.

8. The ferroelectric memory cell of claim 7, wherein the second top electrode is in contact with the second contact and electrically connected between the second ferroelectric capacitor and the second drain region.

9. The ferroelectric memory cell of claim 7, wherein the first ferroelectric dielectric and the second ferroelectric dielectric comprise hafnium oxide (HfOₓ), zirconium oxide (ZrOₓ), titanium oxide (TiOₓ), aluminum oxide (AlOₓ), nickel oxide (NiOₓ), iron oxide (FeOₓ).

10. The ferroelectric memory cell of claim 7, further comprising:
a first blocking layer formed on sidewalls of the first bottom electrode, the first ferroelectric dielectric, and the first top electrode; and
a second blocking layer formed on sidewalls of the second bottom electrode, the second ferroelectric dielectric, and the second top electrode.

11. The ferroelectric memory cell of claim 1, wherein the first ferroelectric capacitor and the second ferroelectric capacitor are in align with each other in a first direction.

12. The ferroelectric memory cell of claim 1, further comprising:
a third ferroelectric capacitor formed on and electrically connected to the first interconnect layer; and
a second plateline formed on and electrically connected to the third ferroelectric capacitor.

13. The ferroelectric memory cell of claim 12, further comprising:
a fourth ferroelectric capacitor formed on and electrically connected to the second plateline, wherein the fourth ferroelectric capacitor is electrically connected to the first ferroelectric capacitor.

14. A ferroelectric memory device, comprising:
a plurality of ferroelectric memory cells, each ferroelectric memory cell comprises:
a transistor pair comprising a first source region, a second source region, a first gate structure, a second gate structure, a first drain region, and a second drain region;
a first ferroelectric capacitor formed on and electrically connected to the first drain region;
a first plateline formed on and electrically connected to the first ferroelectric capacitor; and
a second ferroelectric capacitor formed on and electrically connected to the first plateline, wherein the second ferroelectric capacitor is electrically connected to the second drain region.

15. The ferroelectric memory device of claim 14, wherein each ferroelectric memory cell stores two bits.

16. The ferroelectric memory device of claim 14, wherein the first plateline is configured to be shared among ferroelectric capacitors of the plurality of ferroelectric memory cells laterally.

17. The ferroelectric memory device of claim 14, further comprises a plateline driver, wherein the first plateline is electrically connected to the plateline driver such that a write voltage can be introduced into the plurality of ferroelectric memory cells by the plateline driver.

18. A method for manufacturing a ferroelectric memory cell, comprising:
forming a transistor pair including a first source region, a second source region, a first gate structure, a second gate structure, a first drain region, and a second drain region on a substrate;
forming a first bit line on the first source region, a second bit line on the second source region, a first word line on the first gate structure, and a second word line on the second gate structure;
forming a first contact on the first drain region;
forming a first ferroelectric capacitor on the first contact;
forming a first plateline on the first ferroelectric capacitor;
forming a second ferroelectric capacitor on the first plateline; and
forming an interconnect layer on the second ferroelectric capacitor, wherein the interconnect layer is connected between the second drain region and the second ferroelectric capacitor.

19. The method of claim 18, wherein forming a first ferroelectric capacitor on the first contact comprises:
sequentially forming a first bottom electrode layer, a first ferroelectric dielectric layer, and a first top electrode layer; and
etching the first bottom electrode layer, the first ferroelectric dielectric layer, and the first top electrode layer to form a first bottom electrode, a first ferroelectric dielectric, and a first top electrode.

20. The method of claim 19, further comprising:
forming a first sacrificial blocking layer on sidewalls of the first bottom electrode, the first ferroelectric dielectric, and the first top electrode, and a top surface of the first top electrode;
etching to expose the top surface of the first top electrode to form a first blocking layer; and
forming the first plateline on the top surface of the first top electrode.
